(19) United States
(12) Patent Application Publication
(10) Pub. No.: US 2004/0175933 A1
(43) Pub. Date: Sep. 9, 2004

(54) Method of forming wiring structure

(75) Inventors: Yoshinori Shishida, Yoro-gun (JP); Hiroyuki Watanabe, Bisai-shi (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 10/778,111

(22) Filed: Feb. 17, 2004

(30) Foreign Application Priority Data
Mar. 5, 2003 (JP) JP2003-57974

(51) Int. Cl. H01L 21/20

(52) U.S. Cl. 438/637

(57) ABSTRACT

A method of forming a wiring structure capable of inhibiting a photoresist film for forming an opening from a pattern failure resulting from nitrogen compound gas is obtained. This method of forming a wiring structure comprises steps of forming a first insulator film and a gas permeation suppressive film for suppressing permeation of gas containing nitrogen on a first wiring layer, forming a first opening through the first insulator film and the gas permeation suppressive film, performing at least either heat treatment or retention under a vacuum after forming the first opening, and thereafter forming a second opening through at least the first insulator film.

### BACKGROUND OF THE INVENTION

1. Field of the Invention

The present invention relates to a method of forming a wiring structure, and more particularly, it relates to a method of forming a wiring structure having an opening such as a contact hole (via hole) or a wiring trench.

2. Description of the Background Art

Following the recent scaledown of the design rule for a semiconductor integrated circuit, a wiring width as well as a wiring interval has been increasingly reduced. The wiring resistance is increased when the wiring width is reduced, while the inter-wire capacitance is increased when the wiring interval is reduced. Such increase of the wiring resistance and the inter-wire capacitance results in a remarkable wiring delay.

In general, therefore, a Cu wire having lower resistance increasingly substitutes for an Al wire, in order to reduce the wiring resistance. The Cu wire is generally formed by a dual damascene method, which is disclosed in Japanese Patent Laying-Open No. 2001-77194, for example. According to the dual damascene method, an embedded wire is formed by providing a wiring trench (trench) and a contact hole (via hole) in an insulator film, filling up the wiring trench and the via hole with metals and thereafter removing excess depositional portions of the metals by polishing.

In relation to this dual damascene method, known are a via-first method forming a via hole portion in advance and thereafter forming a trench for a wiring portion in superposition with the pattern of the via hole portion and a trench-first method forming a trench for a wiring portion and thereafter forming a via hole portion in superposition with the pattern of the trench. The via-first method is more advantageous for reliably attaining contact with the via hole.

It has recently been regarded as requisite to reduce the dielectric constant of an interlayer dielectric film in order to reduce the inter-wire capacitance. More specifically, utilization of a fluoridated silicon oxide (SiOF) film, a porosified insulator film or an organic insulator film having a relatively low dielectric constant of about 2 to 3 as compared with a conventional silicon oxide film having a dielectric constant of about 4 is under consideration. Among low dielectric constant materials, an SiOC film (silicon oxide film having a CH₃ group or the like therein), one of organic insulator films, formed by plasma CVD is particularly watched with interest at present.

Thus, a Cu wire and a low dielectric constant SiOC film have been combinedly introduced into a recent semiconductor fabrication process, thereby solving the problem of wiring delay.

FIGS. 22 to 29 are sectional views for illustrating a conventional process of forming a wiring structure employing the via-first method. A conventional method of forming a wiring structure is now described with reference to FIGS. 22 to 29.

As shown in FIG. 22, a gate electrode 105 is formed on a prescribed region of a semiconductor substrate 101 through a gate insulator film 104. The gate electrode 105 is employed as a mask for ion-implanting an impurity into the semiconductor substrate 101, thereby forming a pair of source/drain regions 102 and 103. An interlayer dielectric film 106 is formed to cover the overall surface. A contact hole 106a is formed in the interlayer dielectric film 106 to reach the upper surface of the gate electrode 105. A plug electrode 107 of tungsten (W) or copper (Cu) is formed in the contact hole 106a. An insulator film 108 is formed to cover the overall surface, and a wiring trench (trench) 108a is thereafter formed in the insulator film 108. A first wiring layer 109 of Cu is formed to fill up the trench 108a while coming into contact with the plug electrode 107. Thereafter NH₃ plasma treatment is performed for reducing copper oxide (CuO) formed on the surface of Cu constituting the first wiring layer 109.

Thereafter an SiCN film 110 having functions of stopping etching and preventing diffusion of Cu is formed on the overall surface by plasma CVD employing TMS (trimethylsilane)/NH₃ gas (ammonia gas), as shown in FIG. 23. The surface of the SiCN film 110 is plasma-treated with O₂ gas, in order to improve adhesion with an upper SiOC film 111. Thereafter the SiOC film 111 is formed on the SiCN film 110 by plasma CVD employing TMS (trimethylsilane)/O₂ gas.

As shown in FIG. 24, an organic antireflection coating 112 is formed on the SiOC film 111. Then, a photoresist film 113 is applied to the organic antireflection coating 112 and thereafter subjected to exposure and development, so that a desired via hole pattern is formed therein.

As shown in FIG. 25, the photoresist film 113 is employed as a mask for dry-etching the organic antireflection coating 112 and the SiOC film 111 with CF gas, thereby forming a via hole 120. At this time, the SiCN film 110 is partially thinned (the thinned portion is not illustrated in particular) due to dispersion in etching, though not exposing the first wiring layer 109. Thereafter the photoresist film 113 and the organic antireflection coating 112 are removed.

As shown in FIG. 26, organic antireflection coatings 114 are formed in the via hole 120 and on the SiOC film 111. Then, a photoresist film 115 is applied to the overall surface and thereafter subjected to exposure and development, so that a desired trench pattern is formed therein. Thereafter the photoresist film 115 is employed as a mask for partially dry-etching the organic antireflection coatings 114 and the SiOC film 111 with CF gas, thereby forming a wiring trench (trench) 130 shown in FIG. 27. Thereafter the photoresist films 115 and the organic antireflection coating 114 are removed.

As shown in FIG. 28, the portion of the SiCN film 110 located under the via hole 120 is removed by etching, thereby partially exposing the surface of the first wiring layer 109.

As shown in FIG. 29, a TaN film for preventing diffusion of Cu and a metal film mainly composed of Cu are formed on the upper surface of the SiOC film 111 to fill up the via hole 120 and the trench 130. Excess depositional portions of the metal film and the TaN film located on the upper surface of the SiOC film 111 are removed by polishing. Thus, a barrier layer 116 consisting of the TaN film as well as a second wiring layer 117 and a connection wire 118 consisting of the metal film mainly composed of Cu are simultaneously formed as shown in FIG. 29. A conventional wiring structure is formed in the aforementioned manner.

However, the aforementioned conventional fabrication process has such a problem that the photoresist films 113 and 115 having the via hole pattern and the trench pattern cause pattern failures resulting from nitrogen-based compound gas such as NH₃ gas in formation thereof respectively. This problem is now detailedly described with reference to FIGS. 30 to 33.

In the step of forming the photoresist film 113 having the via hole pattern, photoresist is applied onto the organic antireflection coating 112 provided on the SiOC film 111, thereafter exposed with a KrF laser beam 202 through a via hole photomask 201, and thereafter subjected to PEB (post-exposure baking) and development as shown in FIG. 30, thereby forming the photoresist film 113 having the via hole pattern. In this case, however, nitrogen-based compound gas such as NH₃ gas employed in the NH₃ plasma treatment for reducing the surface of Cu constituting the first wiring layer 109, NH₃ gas employed as material gas for forming the SiCN film 110 or gas resulting from the plasma treatment performed on the surface of the SiCN film 110 for forming the SiOC film 111 is disadvantageously discharged from a portion close to the interface between the first wiring layer 109 and the SiCN film 110 or a portion close to the interface between the SiCN film 110 and the SiOC film 111 toward the photoresist film 113 before the development. This nitrogen-based compound gas disadvantageously inhibits photoresist reaction in the exposure and PEB steps for the photoresist film 113.

More specifically, an unresolved photoresist portion 113a disadvantageously remains under an exposed photoresist portion 113b when the photoresist film 113 is exposed with the KrF laser beam 202 through the via hole photomask 201. The remaining unresolved photoresist portion 113a, which must essentially be rendered dissolvable in a developer and removed, disadvantageously causes a failure in the via hole pattern as shown in FIG. 31. The failure in the via hole pattern shown in FIG. 31 disadvantageously leads to difficulty in formation of the via hole 120.

A similar problem takes place also in formation of the trench pattern. When the photoresist film 115 is exposed with a KrF laser beam 302 through a photomask 301 for trench formation, an unresolved photoresist portion 115a disadvantageously remains under an exposed photoresist portion 115b due to nitrogen-based compound gas (NH₃ gas) from under the via hole 120, as shown in FIG. 32. In this case, the photoresist film 115 disadvantageously causes a failure in the trench pattern as shown in FIG. 33. The failure in the trench pattern shown in FIG. 33 disadvantageously leads to difficulty in formation of the trench 130 with designed dimensions.

### SUMMARY OF THE INVENTION

An object of the present invention is to provide a method of forming a wiring structure capable of inhibiting a photoresist film for forming an opening such as a via hole or a trench from a pattern failure resulting from nitrogen-based compound gas.

In order to attain the aforementioned object, a method of forming a wiring structure according to a first aspect of the present invention comprises steps of forming a first wiring layer, forming a first insulator film on the first wiring layer, forming a gas permeation suppressive film for suppressing permeation of gas containing nitrogen on the first wiring layer, forming a first opening through the first insulator film and the gas permeation suppressive film, performing at least either heat treatment or retention under a vacuum after forming the first opening, and thereafter forming a second opening through at least the first insulator film.

In the method of forming a wiring structure according to the first aspect, as hereinabove described, the gas permeation suppressive film for suppressing permeation of gas containing nitrogen is formed on the first wiring layer and the first opening is thereafter formed through at least the first insulator film, whereby an exposed portion of a photoresist film for forming the first opening can be inhibited from formation of a residue (unresolved portion) resulting from the gas containing nitrogen. Thus, the photoresist film for forming the first opening can be inhibited from a pattern failure. Further, at least either heat treatment or retention under a vacuum is performed after formation of the first opening and the second opening is thereafter formed through the first insulator film and the gas permeation suppressive film so that the gas containing nitrogen is discharged through the first opening due to the heat treatment or the retention under the vacuum, whereby an exposed portion of another photoresist film for forming the second opening can be inhibited from formation of a residue (unresolved portion) resulting from the gas containing nitrogen. Thus, the photoresist film for forming the second opening can be inhibited from a pattern failure.

In the aforementioned method of forming a wiring structure according to the first aspect, the step of forming the gas permeation suppressive film preferably includes a step of forming the gas permeation suppressive film on the first insulator film. According to this structure, the gas permeation suppressive film can inhibit the exposed portion of the photoresist film for forming the first opening from formation of a residue (unresolved portion) resulting from the gas containing nitrogen present on the surface of the first insulator film.

The aforementioned method of forming a wiring structure according to the first aspect preferably further comprises a step of forming a second insulator film between the first wiring layer and the first insulator film, and the step of forming the gas permeation suppressive film preferably includes a step of forming the gas permeation suppressive film between the first insulator film and the second insulator film. According to this structure, the gas permeation suppressive film can inhibit the exposed portion of the photoresist film for forming the first opening from formation of a residue (unresolved portion) resulting from the gas containing nitrogen present in the second insulator film. In this case, the second insulator film may include an SiCN film.

The aforementioned method of forming a wiring structure according to the first aspect may further comprise a step of forming a second insulator film between the first wiring layer and the first insulator film without employing nitrogen-based gas. According to this structure, the second insulator film generates no nitrogen-based compound gas, whereby the quantity of nitrogen-based compound gas can be reduced. Thus, the exposed portion of the photoresist film can be further inhibited from formation of a residue (unresolved portion) resulting from the nitrogen-based compound gas. In this case, the second insulator film may include an SiC film.

In the aforementioned method of forming a wiring structure according to the first aspect, the step of forming the first insulator film preferably includes a step of forming the first insulator film consisting of a plurality of layers, and the step of forming the gas permeation suppressive film preferably includes a step of forming the gas permeation suppressive film also serving as an etching stopper between the plurality of layers of the first insulator film. According to this structure, the gas permeation suppressive film can be employed as an etching stopper in etching for forming the second opening.

In this case, the first insulator film consisting of a plurality of layers may include an SiOC film, and the gas permeation suppressive film may include an SiO₂ film. According to this structure, the gas permeation suppressive film of SiO₂ can be easily employed as an etching stopper for the etching for forming the second opening.

In the aforementioned method of forming a wiring structure according to the first aspect, the first opening is preferably a via hole, and the second opening is preferably a wiring trench. According to this structure, the gas containing nitrogen is more easily discharged through the via hole due to the heat treatment or the retention under a vacuum after formation of the via hole, whereby an exposed portion of a photoresist film for forming the wiring trench can be easily inhibited from formation of a residue (unresolved portion) resulting from the gas containing nitrogen. Thus, the photoresist film for forming the second opening can be easily inhibited from a pattern failure.

In the aforementioned method of forming a wiring structure according to the first aspect, the first insulator film preferably includes an SiOC film. According to this structure, the dielectric constant of the first insulator film can be reduced as compared with that of an SiO₂ film or the like, whereby the inter-wire capacitance between the first and second wiring layers can be reduced.

The aforementioned method of forming a wiring structure according to the first aspect preferably further comprises a step of removing the gas permeation suppressive film after forming the first opening and the second opening. According to this structure, the inter-wire capacitance can be inhibited from increase also when the gas permeation suppressive film is formed by an SiO₂ film or the like having a high dielectric constant.

In this case, the method of forming a wiring structure preferably further comprises a step of forming a second wiring layer in the first opening and the second opening after forming the first opening and the second opening, and the step of removing the gas permeation suppressive film after forming the first opening and the second opening preferably includes a step of removing the gas permeation suppressive film when forming the second wiring layer. According to this structure, no step of removing the gas permeation suppressive film may be newly provided, whereby the fabrication process can be simplified.

In the aforementioned method of forming a wiring structure according to the first aspect, the gas permeation suppressive film preferably includes at least one film selected from a group consisting of an SiO₂ film, an SiN film, an SiC film, an SiCN film, an SiON film, a TaN film, a Ta film and a TiN film. When constituted of such a film, the gas permeation suppressive film can easily suppress permeation of the gas containing nitrogen.

In the aforementioned method of forming a wiring structure according to the first aspect, the step of performing heat treatment preferably includes a step of performing heat treatment at a temperature at least not more than a level equivalent to the formation temperature for the first insulator film. According to this structure, the gas containing nitrogen can be discharged through the first opening due to the heat treatment without damaging the first insulator film.

In the aforementioned method of forming a wiring structure according to the first aspect, the step of performing heat treatment preferably includes a step of performing heat treatment under a decompressed atmosphere. According to this structure, the gas containing nitrogen can be easily discharged through the first opening due to the heat treatment.

In the aforementioned method of forming a wiring structure according to the first aspect, the step of forming the first opening may include a step of forming the first opening with a positive chemically amplified photoresist film, and the step of forming the second opening may include a step of forming the second opening with a positive chemically amplified photoresist film. In such a positive chemically amplified photoresist film, a residue (unresolved portion) of an exposed portion easily results from gas containing nitrogen. When the aforementioned gas permeation suppressive film according to the first aspect is employed, therefore, the exposed portion of the photoresist film can be effectively inhibited from formation of a residue (unresolved portion). In this case, the positive chemically amplified photoresist film may be a photoresist film consisting of a high-temperature baked polymer. A residue (unresolved portion) resulting from gas containing nitrogen is particularly easily formed on an exposed portion in such a photoresist film consisting of a high-temperature baked polymer, and hence the aforementioned gas permeation suppressive film exhibits a large effect of suppressing formation of a residue (unresolved portion).

The aforementioned method of forming a wiring structure according to the first aspect may further comprise a step of plasma-treating the surface of the first wiring layer in an atmosphere containing nitrogen in advance of the step of forming the gas permeation suppressive film. Also when the surface of the first wiring layer is plasma-treated in the atmosphere containing nitrogen, the aforementioned gas permeation suppressive film according to the first aspect can inhibit the exposed portion of the photoresist film from formation of a residue (unresolved portion).

In the aforementioned method of forming a wiring structure according to the first aspect, the step of forming the first opening preferably includes a step of forming the first opening reaching the first wiring layer. According to this structure, no step may be separately provided for removing any insulator film located immediately above the first wiring layer, whereby the fabrication process can be simplified.

A method of forming a wiring structure according to a second aspect of the present invention comprises steps of forming a first wiring layer, forming a first insulator film on the first wiring layer, forming a gas permeation suppressive film for suppressing permeation of gas containing nitrogen on the first wiring layer, forming a first opening through the first insulator film and the gas permeation suppressive film, performing heat treatment after forming the first opening, and thereafter forming a second opening at least through the first insulator film.

In the method of forming a wiring structure according to the second aspect, as hereinabove described, the gas permeation suppressive film for suppressing permeation of the gas containing nitrogen is formed on the first wiring layer and the first opening is thereafter formed at least through the first insulator film, whereby an exposed portion of a photoresist film for forming the first opening can be inhibited from formation of a residue (unresolved portion) resulting from the gas containing nitrogen. Thus, the photoresist film for forming the first opening can be inhibited from a pattern failure. Further, heat treatment is performed after forming the first opening and the second opening is thereafter formed through the first insulator film and the gas permeation suppressive film so that the gas containing nitrogen is discharged through the first opening due to the heat treatment, whereby an exposed portion of another photoresist film for forming the second opening can be inhibited from formation of a residue (unresolved portion) resulting from the gas containing nitrogen. Thus, the photoresist film for forming the second opening can be inhibited from a pattern failure.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 9 are sectional views for illustrating a process of forming a wiring structure according to a first embodiment of the present invention;

FIG. 10 is a sectional view for illustrating a process of forming a wiring structure according to a second embodiment of the present invention;

FIG. 11 is a sectional view for illustrating a process of forming a wiring structure according to a third embodiment of the present invention;

FIGS. 12 and 13 are sectional views for illustrating a process of forming a wiring structure according to a fourth embodiment of the present invention;

FIG. 14 is a sectional view for illustrating a process of forming a wiring structure according to a fifth embodiment of the present invention;

FIG. 15 is a sectional view for illustrating a process of forming a wiring structure according to a sixth embodiment of the present invention;

FIG. 16 is a sectional view for illustrating a process of forming a wiring structure according to a seventh embodiment of the present invention;

FIG. 17 schematically illustrates an SEM-observed surface image of a wiring structure prepared in practice through the process of forming a wiring structure according to the first embodiment;

FIG. 18 schematically illustrates an SEM-observed surface image of a wiring structure according to comparative example 1 employing photoresist consisting of a high-temperature baked polymer in a conventional process of forming a wiring structure;

FIG. 19 schematically illustrates an SEM-observed surface image of a wiring structure according to comparative example 2 employing acetal-based photoresist in the conventional process of forming a wiring structure;

FIG. 20 schematically illustrates an SEM-observed surface image in a case of performing NH₃ plasma treatment for reducing CuO on the surface of a Cu wire constituting a first wiring layer in the conventional process of forming a wiring structure;

FIG. 21 schematically illustrates an SEM-observed surface image in a case of performing no NH₃ plasma treatment for reducing CuO on the surface of a Cu wire constituting a first wiring layer in the conventional process of forming a wiring structure;

FIGS. 22 to 29 are sectional views for illustrating a conventional process of forming a wiring structure; and

FIGS. 30 to 33 are sectional views for illustrating a problem in the conventional process of forming a wiring structure.

### DESCRIPTION OF THE PREFERRED EMBODIMENTS

Embodiments of the present invention are now described with reference to the drawings.

(First Embodiment)

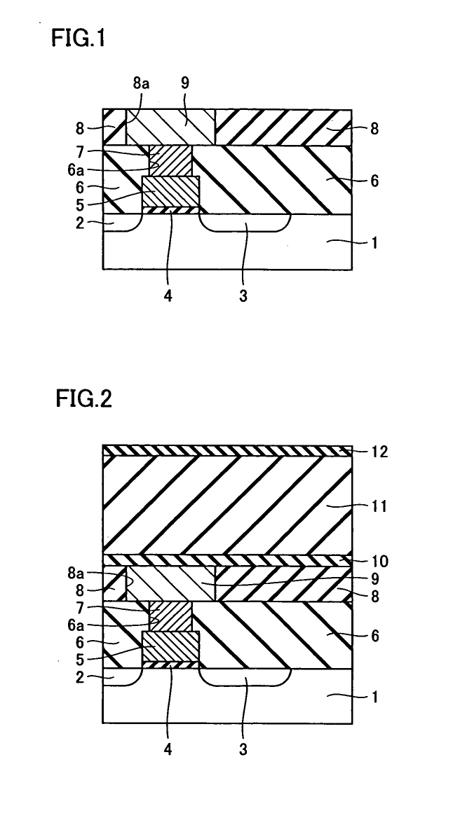

A method of forming a wiring structure according to a first embodiment of the present invention is described with reference to FIGS. 1 to 9.

As shown in FIG. 1, a gate electrode 5 is formed on a prescribed region of a semiconductor substrate 1 through a gate insulator film 4. The gate electrode 5 is employed as a mask for ion-implanting an impurity into the semiconductor substrate 1, thereby forming a pair of source/drain regions 2 and 3. An interlayer dielectric film 6 having a contact hole 6a reaching the upper surface of the gate electrode 5 is formed to cover the overall surface. A plug electrode 7 of W or Cu is formed in the contact hole 6a. An insulator film 8 having a wiring trench (trench) 8a reaching the plug electrode 7 is formed to cover the overall surface. The trench 8a is filled up with copper and an excess copper depositional portion is thereafter removed by CMP, thereby forming a first wiring layer 9 of Cu embedded in the trench 8a.

Plasma treatment is performed with NH₃ gas, for reducing copper oxide (CuO) formed on the surface of the first wiring layer 9.

As shown in FIG. 2, an SiCN film 10 having functions of stopping etching and preventing diffusion of Cu is formed on the overall surface by plasma CVD employing TMS (trimethylsilane)/NH₃ gas (ammonia gas) at a film forming temperature of about 350° C. with a thickness of about 80 nm. In order to improve adhesion with an upper SiOC film 11, the surface of this SiCN film 10 is plasma-treated with O₂ gas. Thereafter the SiOC film 11 is formed on the SiCN film 10 by plasma CVD employing TMS (trimethylsilane)/O₂ gas at a film forming temperature of about 350° C. with a thickness of about 720 nm. The SiCN film 10 is an example of the “second insulator film” in the present invention, and the SiOC film 11 is an example of the “first insulator film” in the present invention.

Nitride-based compound gas (NH₃ gas) is present in the vicinity of the interfaces between the first wiring layer 9 and the SiCN film 10 and between the SiCN film 10 and the SiOC film 11 respectively due to the aforementioned plasma treatment with NH₃ gas and the plasma treatment on the surface of the SiCN film 10.

According to the first embodiment, a gas permeation suppressive film 12 of TEOS-SiO₂ is formed on the SiOC film 11 by plasma CVD employing TEOS (tetraethoxysilane)/O₂ gas with a thickness of about 50 nm. This gas permeation suppressive film 12 has a function of suppressing permeation of the nitride-based compound gas (NH₃ gas).

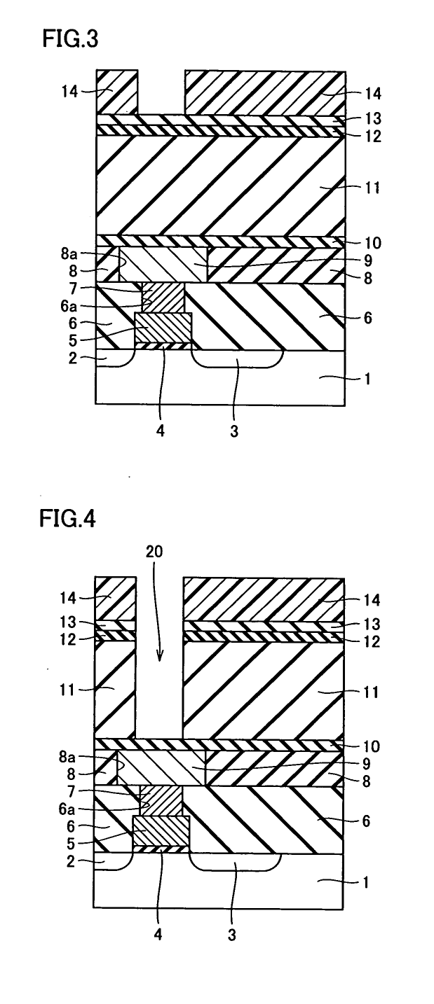

As shown in FIG. 3, an organic antireflection coating 13 is formed on the gas permeation suppressive film 12 with a thickness of about 63 nm. This organic antireflection coating 13 is prepared from DUV30J by Nissan Chemical Industries, Ltd., for example. A photoresist film 14 is applied to the overall surface of the organic antireflection coating 13 and subjected to KrF exposure, PEB and development, so that a desired via hole pattern is formed therein. The photoresist film 14 is prepared from M151Y by JSR, for example.

As shown in FIG. 4, the photoresist film 14 formed with the via hole pattern is employed as a mask for dry-etching the organic antireflection coating 13, the gas permeation suppressive film 12 and the SiOC film 11 with CF gas, thereby forming a via hole 20. The via hole 20 is an example of the “first opening” in the present invention. At this time, the SiCN film 10 is partially thinned (the thinned portion is not illustrated in particular) due to dispersion in etching, though not exposing the first wiring layer 9. Thereafter the photoresist film 14 and the organic antireflection coating 13 are removed by ashing and cleaning.

After formation of the aforementioned via hole 20, heat treatment is performed at about 350° C. for about 2 minutes with a hot plate mounted on a photoresist application/development apparatus (not shown) according to the first embodiment, as shown in FIG. 5. Thus, the nitrogen-based compound gas (NH₃ gas) is discharged through the via hole 20.

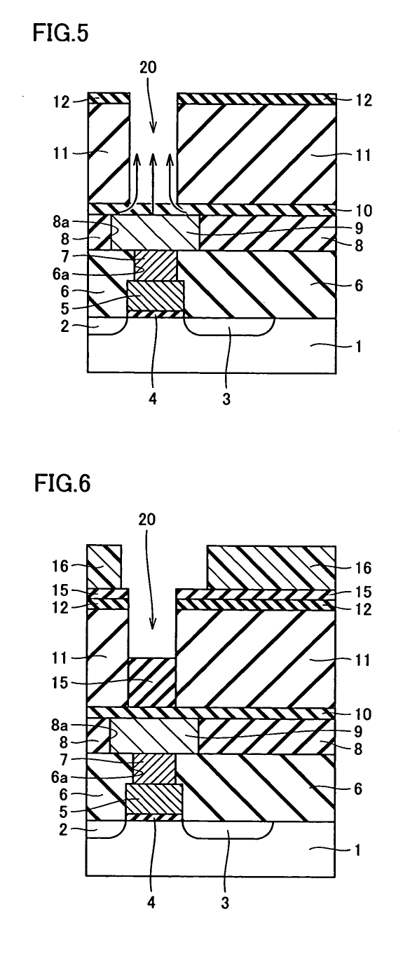

As shown in FIG. 6, another organic antireflection coating 15 is formed on the overall surface with a thickness of about 63 nm. In this case, the organic antireflection coating 15 is deposited also in the via hole 20. This organic antireflection coating 15 is prepared from DUV30J by Nissan Chemical Industries, Ltd., for example. Thereafter a photoresist film 16 is applied to the overall surface with a thickness of about 350 nm and thereafter subjected to KrF exposure, PEB and development, so that a prescribed trench pattern is formed therein. The photoresist film 16 is prepared from YS959 by Shin-Etsu Chemical Co., Ltd., for example. In this case, the nitrogen-based compound gas (NH₃ gas) has already been discharged through the via hole 20 in the step shown in FIG. 5, and hence no nitrogen-based compound gas (NH₃ gas) is discharged toward the photoresist film 16 in the step of exposure, PEB and development for the photoresist film 16 shown in FIG. 6.

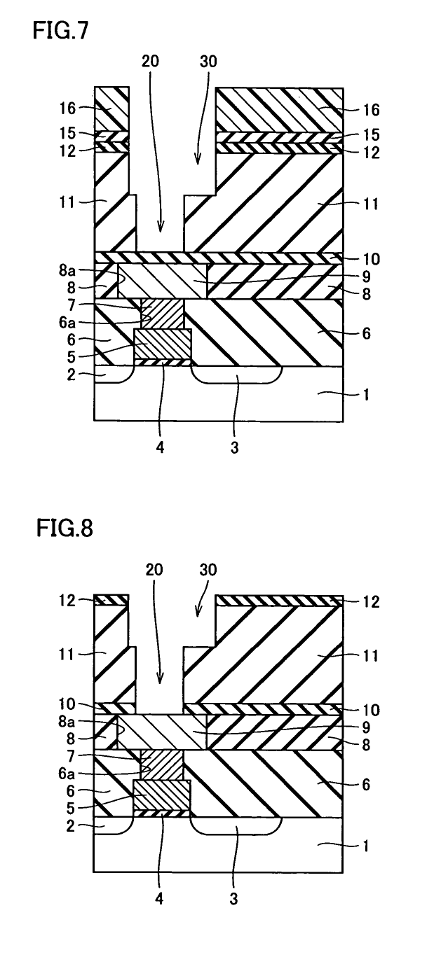

As shown in FIG. 7, the photoresist film 16 is employed as a mask for partially dry-etching the organic antireflection film 15, the gas permeation suppressive film 12 and the SiOC film 11 with CF gas, thereby forming a trench (wiring trench) 30. The trench 30 is an example of the “second opening” in the present invention. Thereafter the photoresist film 16 and the organic antireflection coating 15 are removed by ashing and cleaning.

As shown in FIG. 8, the portion of the SiCN film 10 located on the bottom of the via hole 20 is removed by etching. Thus, the surface of the first wiring layer 9 is partially exposed.

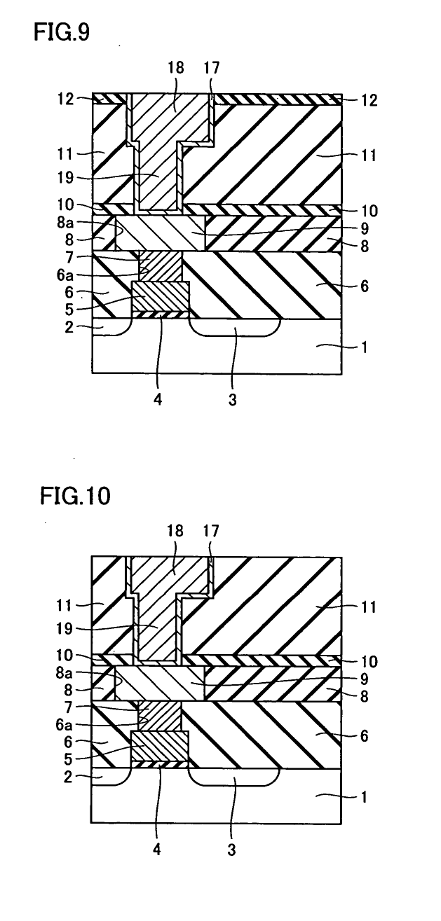

As shown in FIG. 9, a TaN film (thickness: about 50 nm) for preventing diffusion of Cu and a metal film (thickness: about 1000 nm) mainly composed of Cu are formed on the upper surface of the gas permeation suppressive film 12 to fill up the via hole 20 and the trench 30. Excess depositional portions of the metal film and the TaN film located on the upper surface of the gas permeation suppressive film 12 are removed by CMP. Thus, a barrier layer 17 consisting of the TaN film as well as a second wiring layer 18 and a connection wire 19 consisting of the metal film mainly composed of Cu are simultaneously formed. Thus, the wiring structure according to the first embodiment is formed as shown in FIG. 9.

According to the first embodiment, as hereinabove described, the gas permeation suppressive film 12 of TEOS-SiO₂ for suppressing permeation of the nitrogen-based compound gas (NH₃ gas) is formed on the SiOC film 11 so that the nitrogen-based compound gas (NH₃ gas) can be inhibited from being discharged toward the photoresist film 14 from below (in the vicinity of the interface between the SiCN film 10 and the SiOC film 11) when the photoresist film 14 having the via hole pattern is formed by exposure, PEB and development in the step shown in FIG. 3. Thus, a pattern failure can be effectively suppressed when forming the photoresist film 14 having the via hole pattern.

According to the first embodiment, further, the heat treatment is performed after formation of the via hole 20 and before formation of the photoresist film 16 having the trench pattern for previously discharging the nitrogen-based compound gas present in the vicinity of the interface between the first wiring layer 9 and the SiCN film 10 and discharged through the SiCN film 10 located on the bottom of the via hole 20 thinned due to dispersion in etching and the nitrogen-based compound gas (NH₃ gas) present in the vicinity of the interface between the SiCN film 10 and the SiOC film 11 through the via hole 20, whereby the nitrogen-based compound gas (NH₃ gas) can be inhibited from being discharged toward the photoresist film 16 when the photoresist film 16 having the trench pattern is formed by exposure, PEB and development. Thus, a pattern failure can be effectively suppressed when forming the photoresist film 16 having the trench pattern.

According to the first embodiment, in addition, the heat treatment for discharging the nitrogen-based compound gas is performed at the temperature (about 350° C.) not more than a level equivalent to the formation temperature (about 350° C.) for the SiCN film 10 and the SiOC film 11, whereby the nitrogen-based compound gas (NH₃ gas) can be discharged through the via hole 20 without damaging the SiCN film 10 and the SiOC film 11.

(Second Embodiment)

Referring to FIG. 10, a method of forming a wiring structure according to a second embodiment of the present invention is described with reference to a case of finally removing a gas permeation suppressive film 12 dissimilarly to the aforementioned first embodiment.

More specifically, over-polishing is performed when excess depositional portions of a TaN film for forming a barrier layer 17 and a metal film mainly composed of Cu for forming a second wiring layer 18 and a connection wire 19 are removed by CMP in a step similar to that of the first embodiment shown in FIG. 9, thereby also removing the gas permeation suppressive film 12 in the second embodiment. Thus, the structure shown in FIG. 10 is obtained. The remaining steps of the method according to the second embodiment are similar to those of the aforementioned first embodiment.

According to the second embodiment, as hereinabove described, the gas permeation suppressive film 12 is also removed when the excess depositional portions of the TaN film for forming the barrier layer 17 and the metal film mainly composed of Cu for forming the second wiring layer 18 and the connection wire 19 are removed by CMP so that no gas permeation suppressive film 12 consisting of a silicon oxide film (TEOS-SiO₂ film) having a dielectric constant of about 4 is present in an interlayer dielectric film, whereby the dielectric constant of the overall interlayer dielectric film can be reduced. Thus, an inter-wire capacitance can be further reduced as compared with the first embodiment.

The remaining effects of the second embodiment are similar to those of the aforementioned first embodiment.

(Third Embodiment)

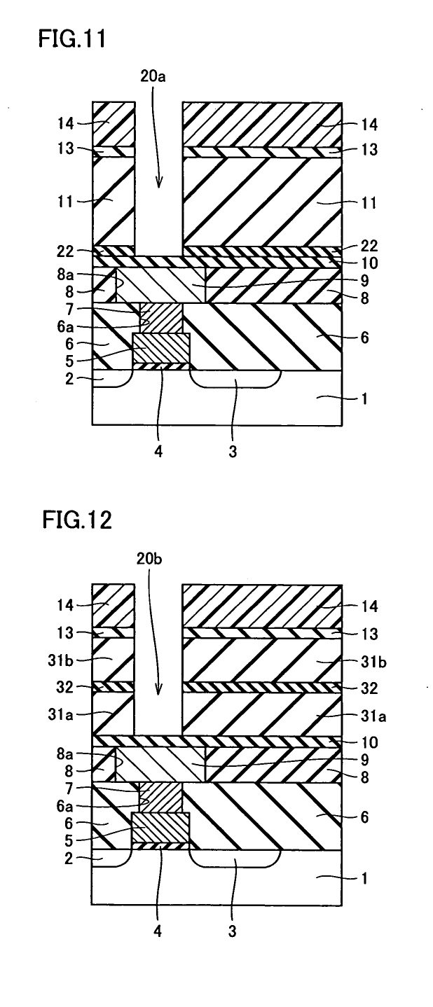

Referring to FIG. 11, a gas permeation suppressive film 22 consisting of a TEOS-SiO₂ film for suppressing permeation of nitrogen-based compound gas is formed between an SiCN film 10 and an SiOC film 11 in a method of forming a wiring structure according to a third embodiment of the present invention, dissimilarly to the aforementioned first embodiment.

More specifically, the gas permeation suppressive film 22 of TEOS-SiO₂, the SiOC film 11 and an organic antireflection coating 13 are successively formed on the SiCN film 10, and a photoresist film 14 having a via hole pattern is thereafter formed on a prescribed region of the organic antireflection coating 13 according to the third embodiment. The photoresist film 14 is employed for dry-etching the organic antireflection coating 13, the SiOC film 11 and the gas permeation suppressive film 22 with CF gas, thereby forming a via hole 20a. The remaining steps of the method according to the third embodiment are similar to those of the aforementioned first embodiment.

According to the third embodiment, as hereinabove described, the gas permeation suppressive film 22 of TEOS-SiO₂ for suppressing permeation of nitrogen-based compound gas is formed between the SiCN film 10 and the SiOC film 11 for suppressing gas permeation on the SiCN film 10 when forming the photoresist film 14 having the via hole pattern by exposure/development, whereby nitrogen-based compound gas (NH₃ gas) positioned on the surface of the SiCN film 10 can be inhibited from upward diffusion. Thus, formation of a pattern failure can be effectively suppressed when forming the photoresist film 14 having the via hole pattern.

The remaining effects of the third embodiment are similar to those of the first embodiment.

(Fourth Embodiment)

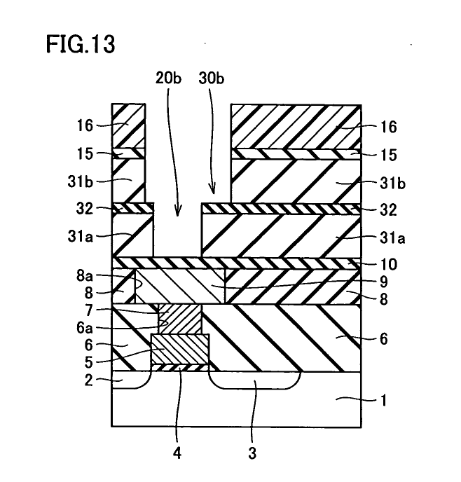

Referring to FIGS. 12 and 13, two SiOC films 31a and 31b are formed so that a gas permeation suppressive film 32 also serving as an etching stopper is formed therebetween in a method of forming a wiring structure according to a fourth embodiment of the present invention, dissimilarly to the aforementioned first embodiment.

More specifically, the SiOC film 31a having a thickness of about 370 nm, the gas permeation suppressive film 32 consisting of a TEOS-SiO₂ film having a thickness of about 50 nm and the SiOC film 31b having a thickness of about 350 nm are successively formed on an SiCN film 10 according to the fourth embodiment, as shown in FIG. 12. An organic antireflection coating 13 is formed on the SiOC film 31b and a photoresist film 14 having a via hole pattern is thereafter formed on a prescribed region of the organic antireflection coating 13. The photoresist film 14 is employed for dry-etching the organic antireflection coating 13, the SiOC film 31b, the gas permeation suppressive film 32 and the SiOC film 31a with CF gas, thereby forming a via hole 20b. Then, steps similar to those of the first embodiment shown in FIGS. 5 and 6 are carried out and another photoresist film 16 is employed as a mask for partially dry-etching another organic antireflection coating 15 and the SiOC film 31b with CF gas thereby forming a trench (wiring trench) 30b. The gas permeation suppressive film 32 functions as an etching stopper in this etching. The remaining steps of the method according to the fourth embodiment are similar to those of the aforementioned first embodiment.

According to the fourth embodiment, as hereinabove described, the gas permeation suppressive film 32 of TEOS-SiO₂ also serving as an etching stopper for forming the trench 30b is formed between the SiOC films 31a and 31b, whereby it is possible to suppress a pattern failure resulting from nitrogen-based compound gas (NH₃ gas) in exposure, PEB and development of the photoresist film 14 having the via hole pattern while easily performing etching for forming the trench 30b.

The remaining effects of the fourth embodiment are similar to those of the first embodiment.

(Fifth Embodiment)

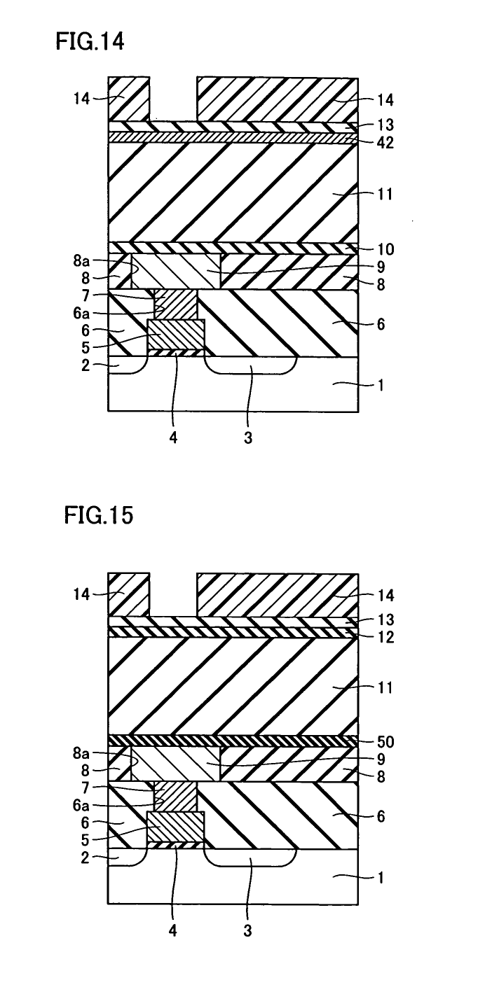

Referring to FIG. 14, a method of forming a wiring structure according to a fifth embodiment of the present invention is described with reference to a case of forming a gas permeation suppressive film 42 consisting of a TaN film, i.e., a metal film, dissimilarly to the first to fourth embodiments employing the gas permeation suppressive films 12, 22 and 32 consisting of TEOS-SiO₂ films, i.e., insulator films. The remaining steps of the method according to the fifth embodiment are similar to those of the first embodiment.

More specifically, the gas permeation suppressive film 42 consisting of a TaN film, i.e., a metal film having a thickness of about 50 nm is formed on an SiOC film 11 by sputtering according to the fifth embodiment, as shown in FIG. 14. An organic antireflection coating 13 is formed on the gas permeation suppressive film 42, and a photoresist film 14 having a via hole pattern is thereafter formed on a prescribed region of organic antireflection coating 13.

According to the fifth embodiment, as hereinabove described, the gas permeation suppressive film 42 is formed by a TaN film, i.e., a metal film, whereby the function of suppressing permeation of nitrogen-based compound gas (NH₃ gas) can be further improved as compared with the gas permeation suppressive film 12 of TEOS-SiO₂. Further, the thickness of the gas permeation suppressive film 42 can be reduced due to the high effect of suppressing permeation of nitrogen-based compound gas.

According to the fifth embodiment, further, the gas permeation suppressive film 42 is formed by a TaN film identically to a barrier layer 17 so that the gas permeation suppressive film 42 of TaN can be continuously removed under the same conditions as those for the barrier layer 17 of TaN when excess depositional portions of a TaN film for forming the barrier layer 17 and a metal film mainly composed of Cu for forming a second wiring layer 18 and a connection wire 19 are removed by CMP in a step similar to that shown in FIG. 9.

The remaining effects of the fifth embodiment are similar to those of the first embodiment.

(Sixth Embodiment)

Referring to FIG. 15, a method of forming a wiring structure according to a sixth embodiment of the present invention is described with reference to a case of forming an SiC film 50 having functions of stopping etching and preventing Cu diffusion in place of the SiCN film 10 in the first embodiment. The remaining steps of the method according to the sixth embodiment are similar to those of the first embodiment.

More specifically, a first wiring layer 9 of Cu is formed and the SiC film 50 having a thickness of about 80 nm is thereafter formed by plasma CVD with TMS (trimethylsilane)/He (helium) gas in the sixth embodiment, as shown in FIG. 15. This SiC film 50 has functions of stopping etching and preventing Cu diffusion, similarly to the SiCN film 10 in the first embodiment. Thereafter an SiOC film 11, a gas permeation suppressive film 12 of TEOS-SiO₂, an organic antireflection coating 13 and a photoresist film 14 having a via hole pattern are formed through steps similar to those of the first embodiment. The photoresist film 14 is employed for dry-etching the organic antireflection coating 13, the SiOC film 11 and the SiC film 50 with CF gas, thereby forming a via hole 20. At this time, the SiC film 50 is partially thinned (the thinned portion is not illustrated in particular) due to dispersion in etching, though not exposing the first wiring layer 9.

According to the sixth embodiment, the SiOC film 11 is formed on the SiC film 50 containing no N so that no nitrogen-based compound gas is present in the vicinity of the interface between the SiC film 50 and the SiOC film 11. Further, the SiC film 50 containing no nitrogen (N) in the material gas therefor is formed on the first wiring layer 9 so that no nitrogen-based compound gas (NH₃ gas) is generated dissimilarly to the case of forming the SiCN film 10. However, nitrogen-based compound gas (NH₃ gas) is present in the vicinity of the interface between the first wiring layer 9 and the SiC film 50 due to plasma treatment with NH₃ gas for reducing the surface of the first wiring layer 9. In formation of a trench pattern, therefore, the nitrogen-based compound gas is discharged through the portion, thinned by dispersion in etching for forming the via hole 20, of the SiC film 50 located on the bottom of the via hole 20. Consequently, the method according to the sixth embodiment also requires heat treatment for discharging the gas.

(Seventh Embodiment)

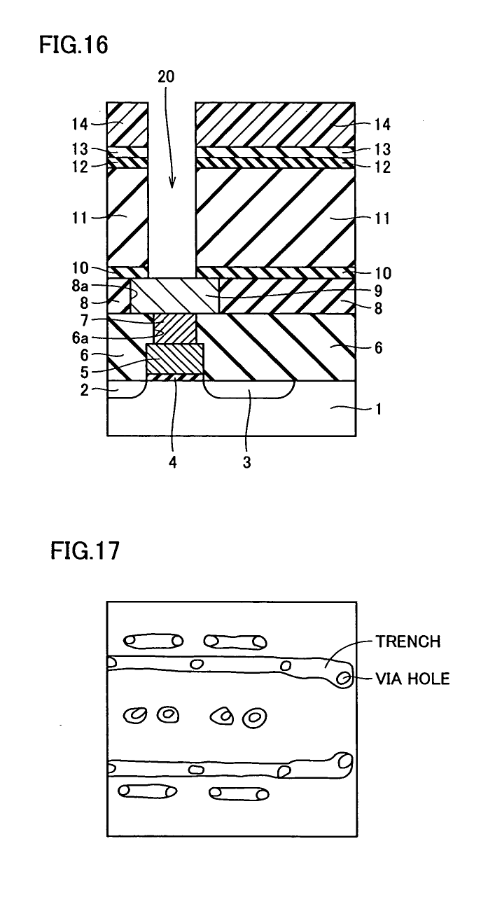

Referring to FIG. 16, an SiCN film 10 is removed by etching along with an organic antireflection coating 13, a gas permeation suppressive film 12 and an SiOC film 11 in a step of forming a via hole 20 similar to that of the first embodiment shown in FIG. 4 in a method of forming a wiring structure according to a seventh embodiment of the present invention. According to this structure, no step of removing the SiCN film 10 (see FIG. 8) may be separately provided and hence the fabrication process can be further simplified.

The remaining effects of the seventh embodiment are similar to those of the first embodiment.

An experiment made for confirming the effects of the aforementioned first embodiment is now described. Positive chemically amplified photoresist is rendered dissolvable in a developer due to catalytic action of acid. More specifically, the catalytic action of acid progresses due to evolution of acid by exposure and diffusion of acid by PEB, to render the photoresist dissolvable in the developer. Acetal photoresist or photoresist consisting of a high-temperature baked polymer such as YS959 by Shin-Etsu Chemical Co., Ltd. employed in the aforementioned first embodiment is known as such positive chemically amplified photoresist.

The acetal photoresist is lower in resolution as compared with photoresist consisting of a high-temperature baked polymer mainly used in a process following 0.18 μm, while reaction upon acid evolution is dominant in catalytic action of acid and hence the catalytic action of acid remarkably progress upon evolution of acid resulting from exposure. Thus, influence by disappearance of acid caused by nitrogen-based compound gas between exposure and PEB is conceivably small. When an acetal-based photoresist film is employed, therefore, the photoresist film conceivably hardly causes a pattern failure. Therefore, the following comparative experiment was carried out: First, a wiring structure was prepared in practice through the method of forming a wiring structure according to the aforementioned first embodiment. In this case, a photoresist film having a trench pattern was prepared from YS959, a sort of photoresist film employing a high-temperature baked polymer, by Shin-Etsu Chemical Co., Ltd. FIG. 17 schematically illustrates an SEM-observed surface image of the photoresist film having the trench pattern.

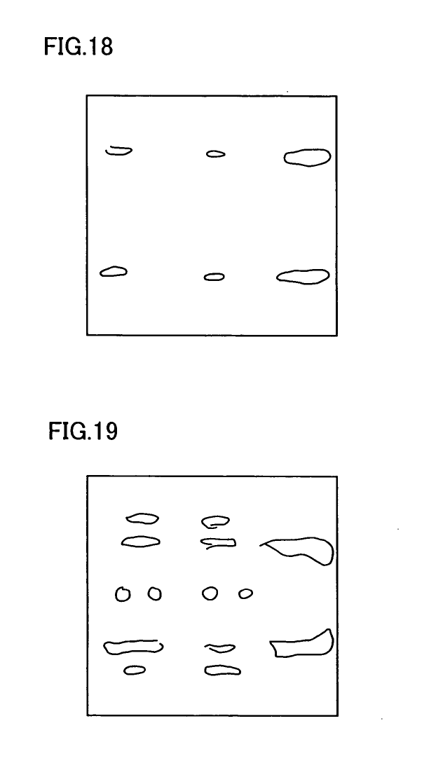

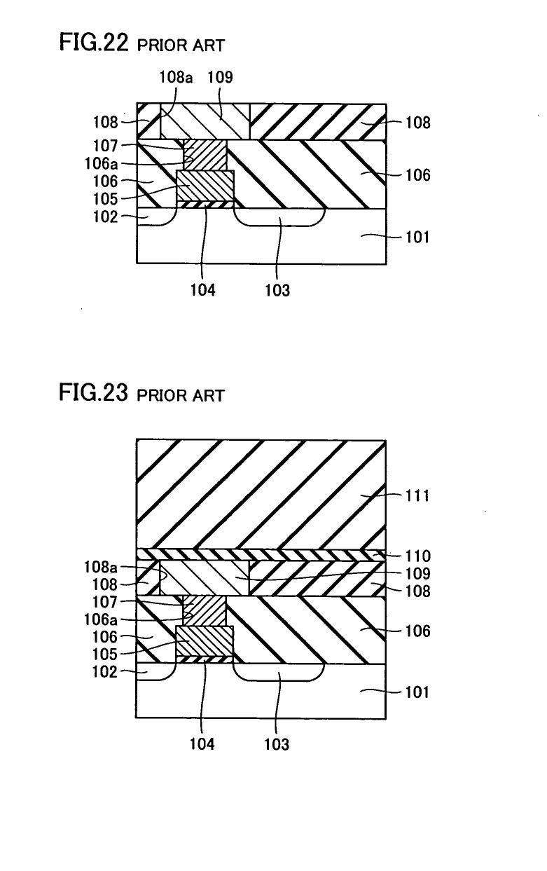

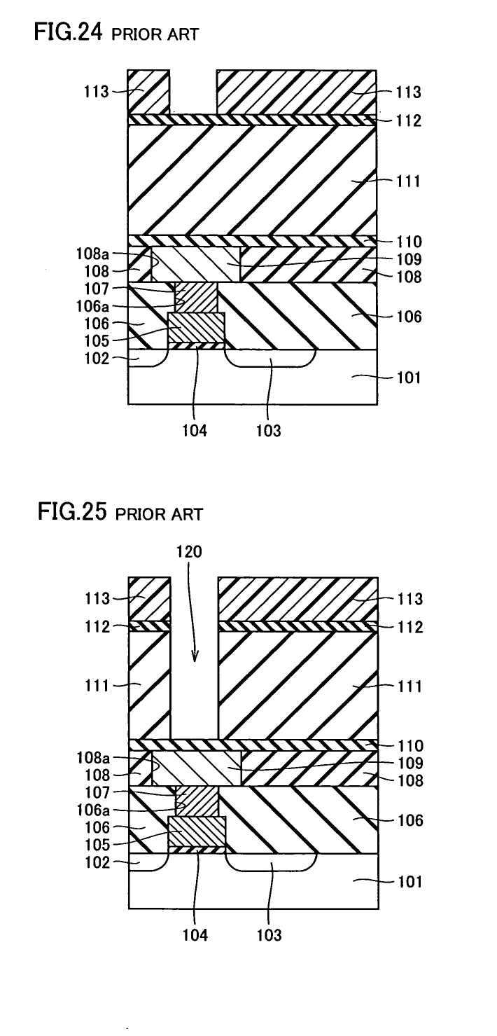

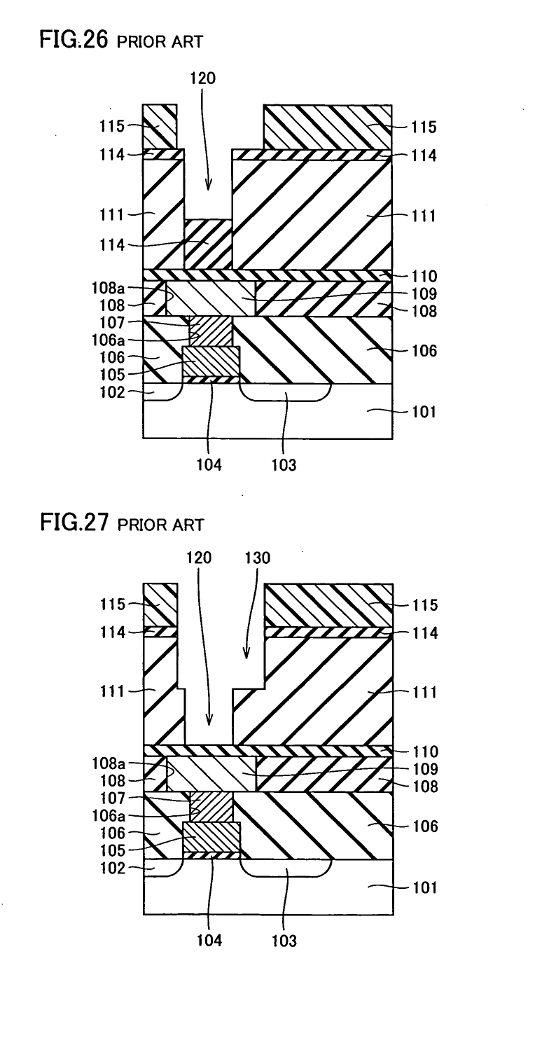

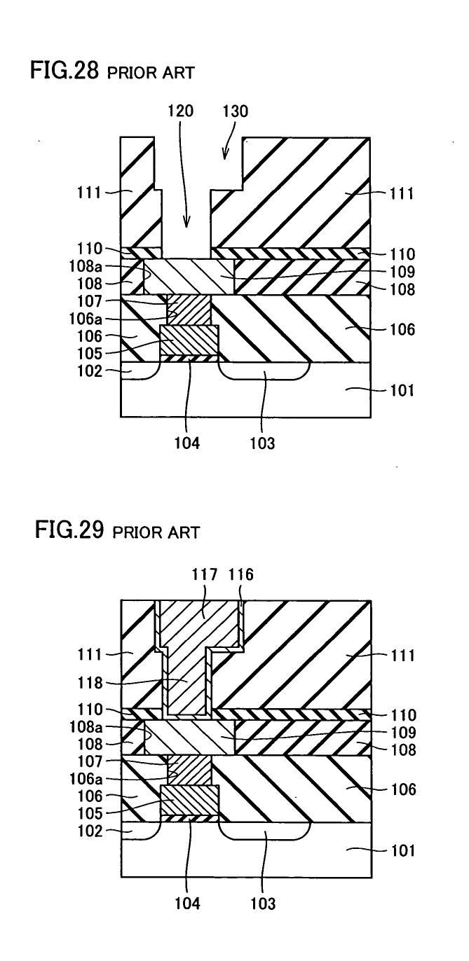

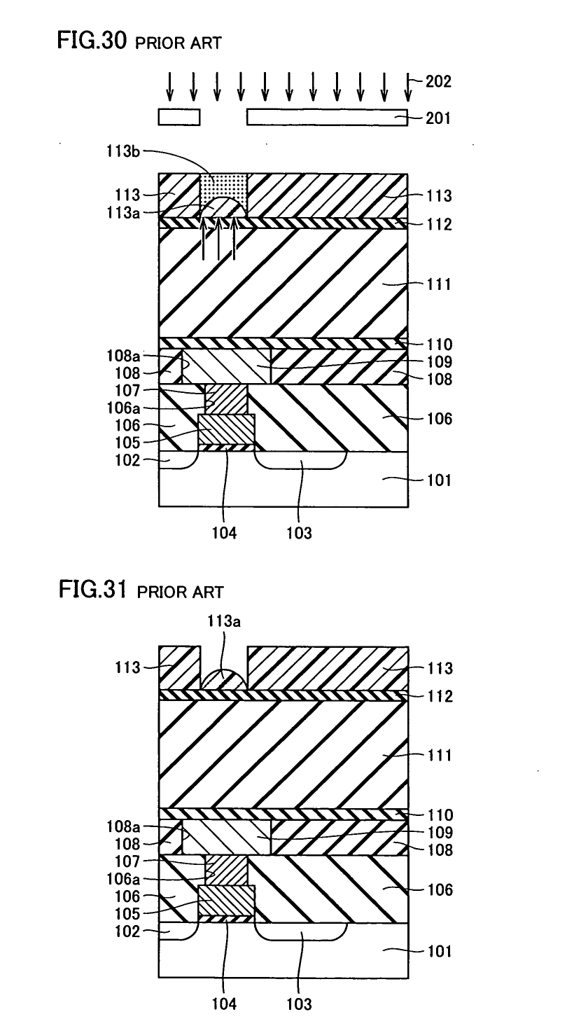

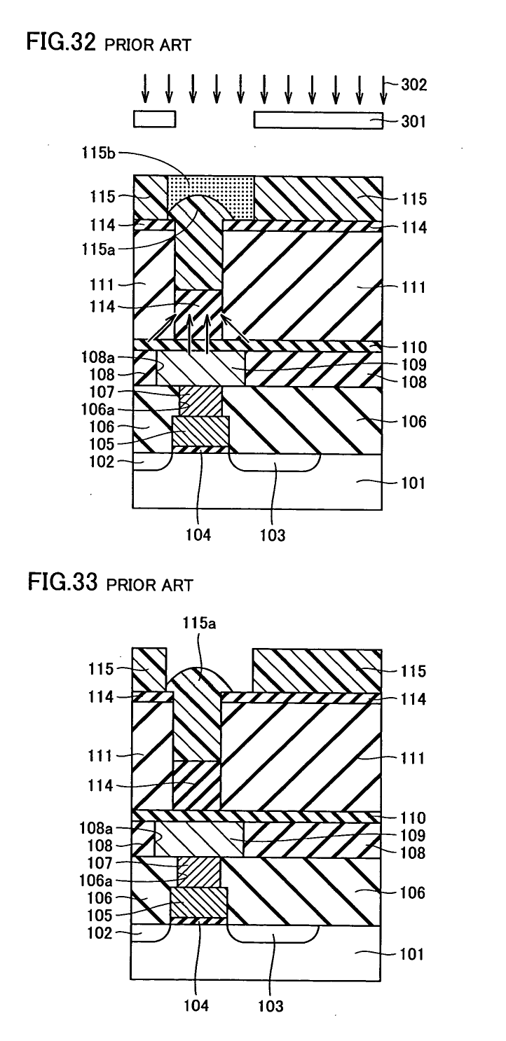

According to the conventional method of forming a wiring structure shown in FIGS. 22 to 29, photoresist films having trench patterns were prepared from a photoresist film consisting of a high-temperature baked polymer (YS959 by Shin-Etsu Chemical Co., Ltd.) and that prepared from acetal photoresist (TDUR-P383 by Tokyo Ohka Kogyo Co., Ltd.) respectively and subjected to the experiment as comparative examples 1 and 2 respectively. More specifically, an SiCN film was formed with a thickness of 80 nm and an SiOC film having a thickness of 720 nm was thereafter formed on the SiCN film in comparative example 1. A via hole was formed by dry etching, followed by application of an organic antireflection coating (DUV30J by Nissan Chemical Industries, Ltd., thickness: 63 nm) and a photoresist film of a high-temperature baked polymer (YS959 by Shin-Etsu Chemical Co., Ltd., thickness: 350 nm), KrF exposure and development. FIG. 18 schematically illustrates an SEM-observed surface image of the photoresist film having the trench pattern according to comparative example 1.

In comparative example 2, an acetal photoresist film (TDUR-P383 by Tokyo Ohka Kogyo Co., Ltd., thickness: 350 nm) was employed in place of the photoresist film consisting of a high-temperature baked polymer in the aforementioned process. FIG. 19 schematically illustrates an SEM-observed surface image of the photoresist film having a trench pattern according to comparative example 2.

Referring to FIG. 17, it has been confirmed that the wiring structure formed by the method according to the first embodiment caused no trench pattern failure. On the other hand, it is understood that the photoresist film of a high-temperature baked polymer according to comparative example 1 shown in FIG. 18, having a number of portions formed with no trench patterns, easily caused trench pattern failures. It is also understood that the photoresist film of acetal photoresist according to comparative example 2 shown in FIG. 19, including regions formed with no trench patterns although the number of regions formed with trench patterns, caused trench pattern failures. Thus, it has been clarified that the effect of suppressing pattern failures by employing acetal photoresist is insufficient. It has been possible to confirm from the aforementioned experimental results that the method of forming a wiring structure according to the first embodiment is effective for suppressing a pattern failure.

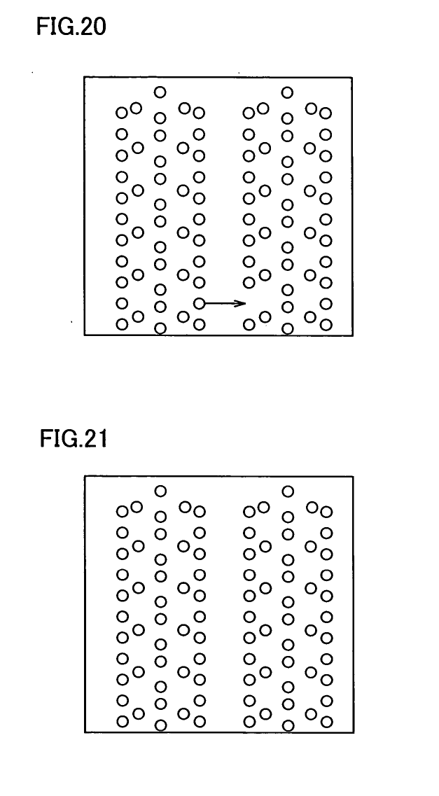

Another experiment performed for confirming influence by NH₃ plasma treatment for reducing CuO on the surface of a first wiring layer is described with reference to FIGS. 20 and 21. FIGS. 20 and 21 schematically illustrate SEM-observed surface images after formation of via holes and before formation of trenches in a case of performing NH₃ plasma treatment and a case of performing no NH₃ plasma treatment respectively. In this experiment, an SiC film of 80 nm in thickness and an SiOC film of 720 nm in thickness were successively formed on a first wiring layer and a via hole was thereafter formed to pass through the SiOC film according to the conventional method of forming a wiring structure shown in FIGS. 22 to 29 in each case. Then, a trench pattern was formed. In the case of performing the NH₃ plasma treatment for reducing CuO on the surface of a Cu wire, a pattern failure was confirmed in a photoresist film having a via hole pattern on a position shown by arrow in FIG. 20.

In the case of performing no NH₃ plasma treatment, on the other hand, no pattern failure was confirmed in a photoresist film having a via hole pattern as shown in FIG. 21. When no NH₃ plasma treatment is performed, however, the wiring resistance of the first wiring layer consisting of Cu is disadvantageously remarkably increased due to CuO remaining on the surface of Cu, as shown in FIG. 21. Thus, it is conceivably difficult to omit the NH₃ plasma treatment for reducing CuO in the first wiring layer. Therefore, the photoresist film is preferably inhibited from a pattern failure resulting from the NH₃ plasma treatment for reducing CuO on the surface of the first wiring layer by employing the method of forming a wiring structure according to any of the aforementioned first to seventh embodiments

The inventor has experimentally confirmed that nitrogen-based compound gas is dominantly discharged through a via hole upon heating. In other words, the inventor has confirmed that no effect of suppressing a pattern failure is attained when heat treatment is performed after formation of an SiOC film without forming a gas permeation suppressive film and thereafter forming a photoresist film having a via hole pattern on the SiOC film. Thus, it has been proved that no heat treatment but only formation of a gas permeation suppressive film is effective for suppressing a pattern failure in formation of a photoresist film having a via hole pattern. On the other hand, no gas permeation suppressive film but only heat treatment after formation of a via hole is effective for suppressing a pattern failure in formation of a photoresist film having a trench pattern. Thus, it is conceivably necessary and inevitable to combine formation of a gas permeation suppressive film and heat treatment after formation of a via hole with each other.

Although the present invention has been described and illustrated in detail, it is clearly understood that the same is by way of illustration and example only and is not to be taken by way of limitation, the spirit and scope of the present invention being limited only by the terms of the appended claims.

For example, while the insulator film such as an SiCN film or an SiC film and the metal film such as a TaN film are employed for forming the gas permeation suppressive film 12, 22, 32 or 42 for suppressing permeation of the nitrogen-based compound gas in each of the aforementioned embodiments, the present invention is not restricted to this but another insulator film and another metal film having functions of suppressing permeation of nitrogen-based compound gas may alternatively be employed. For example, an SiO₂ film, an SiN film or an SiON film is conceivable as another insulator film constituting the gas permeation suppressive film 12, 22, 32 or 42. Further, a Ta film or a TiN film is conceivable as another metal film constituting the gas permeation suppressive film 12, 22, 32 or 42.

While the present invention is applied to the two-layer wiring structure having the first and second wiring layers 9 and 18 in each of the aforementioned embodiment, the present invention is not restricted to this but is also applicable to a wiring structure having three or more layers. In order to form a multilayer wiring structure having three or more layers employing a Cu wire and a low dielectric constant SiOC film, for example, the process according to the aforementioned first embodiment may be repeated.

While the SiC film 50 formed without nitrogen-based gas is employed as the film having functions of stopping etching and preventing Cu diffusion in the aforementioned sixth embodiment, the present invention is not restricted to this but another film such as a TEOS-SiO₂ film formed without nitrogen-based gas may alternatively be employed as the film having functions of stopping etching and preventing Cu diffusion.

While the heat treatment for discharging the nitrogen-based gas is performed under the conditions of 350° C. for about 2 minutes in each of the aforementioned embodiments, the present invention is not restricted to this but the heat treatment may alternatively be performed at another temperature so far as this temperature is not more than a level equivalent to a temperature (about 350° C.) for forming an interlayer film such as an SiCN film or an SiON film. The inventor has confirmed that a similar effect can be attained also when performing heat treatment at about 250° C. for about 20 minutes. When the heat treatment is performed under decompression, the gas is more effectively discharged.

While the positive chemically amplified photoresist for a KrF laser beam is employed in each of the aforementioned embodiments, the present invention is not restricted to this but a similar effect can be attained also when employing positive chemically amplified photoresist applied to an ArF, F₂ or EPL laser beam.

While the present invention is applied to the via-first method forming a via hole and thereafter forming a trench in each of the aforementioned embodiments, the present invention is not restricted to this but a similar effect is attained also when applying the present invention to the trench-first method forming a trench and thereafter forming a via hole.

While the heat treatment is performed for discharging the nitrogen-based gas in each of the aforementioned embodiments, the present invention is not restricted to this but the nitrogen-based gas may alternatively be discharged by another method. For example, it is also possible to discharge the nitrogen-based gas by retention in a vacuum.

What is claimed is:

1. A method of forming a wiring structure, comprising steps of:
forming a first wiring layer;
forming a first insulator film on said first wiring layer;
forming a gas permeation suppressive film for suppressing permeation of gas containing nitrogen on said first wiring layer;
forming a first opening through said first insulator film and said gas permeation suppressive film;
performing at least either heat treatment or retention under a vacuum after forming said first opening; and
thereafter forming a second opening through at least said first insulator film.

2. The method of forming a wiring structure according to claim 1, wherein
said step of forming said gas permeation suppressive film includes a step of forming said gas permeation suppressive film on said first insulator film.

3. The method of forming a wiring structure according to claim 1, further comprising a step of forming a second insulator film between said first wiring layer and said first insulator film,
said step of forming said gas permeation suppressive film including a step of forming said gas permeation suppressive film between said first insulator film and said second insulator film.

4. The method of forming a wiring structure according to claim 3, wherein
said second insulator film includes an SiCN film.

5. The method of forming a wiring structure according to claim 1, further comprising a step of forming a second insulator film between said first wiring layer and said first insulator film without employing nitrogen-based gas.

6. The method of forming a wiring structure according to claim 5, wherein
said second insulator film includes an SiC film.

7. The method of forming a wiring structure according to claim 1, wherein
said step of forming said first insulator film includes a step of forming said first insulator film consisting of a plurality of layers, and
said step of forming said gas permeation suppressive film includes a step of forming said gas permeation suppressive film also serving as an etching stopper between said plurality of layers of said first insulator film.

8. The method of forming a wiring structure according to claim 7, wherein
said first insulator film consisting of a plurality of layers includes an SiOC film, and
said gas permeation suppressive film includes an SiO₂ film.

9. The method of forming a wiring structure according to claim 1, wherein
said first opening is a via hole, and
said second opening is a wiring trench.

10. The method of forming a wiring structure according to claim 1, wherein
said first insulator film includes an SiOC film.

11. The method of forming a wiring structure according to claim 1, further comprising a step of removing said gas permeation suppressive film after forming said first opening and said second opening.

12. The method of forming a wiring structure according to claim 11, further comprising a step of forming a second wiring layer in said first opening and said second opening after forming said first opening and said second opening,
said step of removing said gas permeation suppressive film after forming said first opening and said second opening includes a step of removing said gas permeation suppressive film when forming said second wiring layer.

13. The method of forming a wiring structure according to claim 1, wherein
said gas permeation suppressive film includes at least one film selected from a group consisting of an SiO₂ film, an SiN film, an SiC film, an SiCN film, an SiON film, a TaN film, a Ta film and a TiN film.

14. The method of forming a wiring structure according to claim 1, wherein
said step of performing heat treatment includes a step of performing heat treatment at a temperature at least not more than a level equivalent to the formation temperature for said first insulator film.

15. The method of forming a wiring structure according to claim 1, wherein
said step of performing heat treatment includes a step of performing heat treatment under a decompressed atmosphere.

16. The method of forming a wiring structure according to claim 1, wherein
said step of forming said first opening includes a step of forming said first opening with a positive chemically amplified photoresist film, and
said step of forming said second opening includes a step of forming said second opening with a positive chemically amplified photoresist film.

17. The method of forming a wiring structure according to claim 16, wherein
said positive chemically amplified photoresist film is a photoresist film consisting of a high-temperature baked polymer.

18. The method of forming a wiring structure according to claim 1, further comprising a step of plasma-treating the surface of said first wiring layer in an atmosphere containing nitrogen in advance of said step of forming said gas permeation suppressive film.

19. The method of forming a wiring structure according to claim 1, wherein
said step of forming said first opening includes a step of forming said first opening reaching said first wiring layer.

20. A method of forming a wiring structure, comprising steps of:
forming a first wiring layer;
forming a first insulator film on said first wiring layer;
forming a gas permeation suppressive film for suppressing permeation of gas containing nitrogen on said first wiring layer;
forming a first opening through said first insulator film and said gas permeation suppressive film;
performing heat treatment after forming said first opening; and
thereafter forming a second opening at least through said first insulator film.
